(19) United States
(12) Patent Application Publication
(10) Pub. No.: US 2018/0108966 A1
(43) Pub. Date: Apr. 19, 2018

(54) SIGNAL TRANSMISSION LINE INCLUDING ELECTRICALLY THIN RESISTIVE LAYER AND ASSOCIATED METHODS

(71) Applicant: Keysight Technologies, Inc., Minneapolis, MN (US)

(72) Inventors: Gregory S. Lee, Mountain View, CA (US); Lewis R. Dove, Monument, CO (US)

(21) Appl. No.: 15/820,988

(22) Filed: Nov. 22, 2017

Related U.S. Application Data
(63) Continuation-in-part of application No. 14/823,997, filed on Aug. 11, 2015.
Application No. 14/823,997 is a continuation-in-part of application No. 15/008,368, filed on Jan. 27, 2016.

(51) Int. Cl. H01P 3/06; H01P 3/08; H01P 3/12; H01P 5/107; H01P 1/16; H01Q 13/08; H03C 7/02

(52) U.S. Cl. CPC H01P 3/06; H01P 3/081; H01P 3/121; H03C 7/02; H01P 1/16; H01Q 13/08; H01P 5/107

(57) ABSTRACT

A signal transmission line includes: a first electrical conductor; a second electrical conductor; a dielectric region between the first electrical conductor and the second electrical conductor; and an electrically thin resistive layer disposed within the dielectric region and disposed between the first electrical conductor and the second electrical conductor. A gap exists in the electrically thin resistive layer.

### CROSS REFERENCE TO RELATED APPLICATIONS

This application is a continuation-in-part application under 37 C.F.R. § 1.53(b)(2) of commonly owned U.S. patent application Ser. No. 14/823,997 to Dove, et al. entitled “Coaxial Transmission Line Including Electrically Thin Resistive Layer and Associated Methods” filed on Aug. 11, 2015, and Ser. No. 15/008,368 to Dove, et al. entitled “Signal Transmission Line and Electrical Connector Including Electrically Thin Resistive Layer and Associated Methods” filed on Jan. 27, 2016. The present application claims priority under 35 U.S.C. § 120 to U.S. patent application Ser. Nos. 14/823,997 and 15/008,368, the disclosures of which are hereby incorporated by reference in their entirety.

### BACKGROUND

Signal transmission lines (‘transmission lines’) are ubiquitous in modern communications. These transmission lines transmit electromagnetic (EM) signals (‘signals’) from point to point, and take on various known forms including stripline, microstripline (‘microstrip’), and coaxial (“coax”) transmission lines, to name a few.

It is desirable for these transmission lines to support a single eigenmode (‘single mode’) of signal propagation. Multi-mode signal propagation is problematic because the desired propagation mode and higher-order modes may interfere with each other to provide a received signal that is severely frequency-dependent in an uncontrolled and usually un-interpretable manner. This is analogous to the well-known multipath problem in wireless propagation, except in this instance the problem occurs in a “wired” setting. In high-bandwidth, high-quality signal environments multi-mode signal propagation is typically unacceptable.

What is needed, therefore, is a transmission line that fosters discrimination of a desired TEM mode of signal propagation from the higher-order modes with minimal attenuation of the TEM mode.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a cross-sectional view of a coaxial transmission line in accordance with a representative embodiment.

FIG. 2 is a cross-sectional view of the representative embodiment of FIG. 1 illustrating the TEM mode electric field.

FIG. 3 is a perspective view of the representative embodiment of FIG. 1.

FIG. 4 is a cross-sectional view of a coaxial transmission line in accordance with a representative embodiment.

FIG. 5 is a side view of a coaxial transmission line in accordance with a representative embodiment.

FIGS. 6 and 7 are tables illustrating mode cutoff eigenvalues of higher order modes, for a 50-ohm coaxial cable, that may/may not be attenuated in the representative embodiments.

FIG. 8 is a cross-sectional view of a transmission line in accordance with a representative embodiment.

FIG. 9 is a cross-sectional view of a microstrip line (microstrip) transmission line in accordance with a representative embodiment.

FIG. 10 is a cross-sectional view of a microstrip transmission line in accordance with a representative embodiment.

FIG. 11 is a cross-sectional view of a stripline transmission line in accordance with a representative embodiment.

FIG. 12 is a cross-sectional view of a stripline transmission line in accordance with a representative embodiment.

FIG. 13 is a perspective view of a coaxial transmission line in accordance with a representative embodiment.

FIG. 14 is a perspective view of a coaxial transmission line in accordance with a representative embodiment.

FIG. 15 is a perspective view of a coaxial transmission line in accordance with a representative embodiment.

FIG. 16 is a perspective view of a coaxial transmission line in accordance with a representative embodiment.

FIG. 17 is a perspective view of a coaxial transmission line in accordance with a representative embodiment.

FIG. 18 is a perspective view of a coaxial transmission line in accordance with a representative embodiment.

FIG. 19 is a perspective view of a coaxial transmission line in accordance with a representative embodiment.

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical and scientific meanings of the defined terms as commonly understood and accepted in the technical field of the present teachings.

Unless otherwise noted, when a first element (e.g., a signal transmission line) is said to be connected to a second element (e.g., another signal transmission line), this encompasses cases where one or more intermediate elements (e.g., an electrical connector) may be employed to connect the two elements to each other. However, when a first element is said to be directly connected to a second element, this encompasses only cases where the two elements are connected to each other without any intermediate or intervening devices. Similarly, when a signal is said to be coupled to an element, this encompasses cases where one or more intermediate elements may be employed to couple the signal to the element. However, when a signal is said to be directly coupled to an element, this encompasses only cases where the signal is directly coupled to the element without any intermediate or intervening devices.

As used in the specification and appended claims, the terms ‘a’, ‘an’ and ‘the’ include both singular and plural referents, unless the context clearly dictates otherwise. Thus, for example, ‘a device’ includes one device and plural devices. As used in the specification and appended claims, and in addition to their ordinary meanings, the terms ‘substantial’ or ‘substantially’ mean to within acceptable limits or degree. As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

Relative terms, such as “above,” “below,” “top,” “bottom,” may be used to describe the various elements' relationships to one another, as illustrated in the accompanying drawings. These relative terms are intended to encompass different orientations of the elements thereof in addition to the orientation depicted in the drawings. For example, if an apparatus (e.g., a semiconductor package) depicted in a drawing were inverted with respect to the view in the drawings, an element described as “above” another element, for example, would now be “below” that element. Similarly, if the apparatus were rotated by 90° with respect to the view in the drawings, an element described “above” or “below” another element would now be “adjacent” to the other element; where “adjacent” means either abutting the other element, or having one or more layers, materials, structures, etc., between the elements.

In accordance with a representative embodiment, a signal transmission line comprises: a first electrical conductor; a second electrical conductor; a dielectric region between the first electrical conductor and the second electrical conductor; and an electrically thin resistive layer having disposed within the dielectric region and disposed between the first electrical conductor and the second electrical conductor. A gap exists in the electrically thin resistive layer.

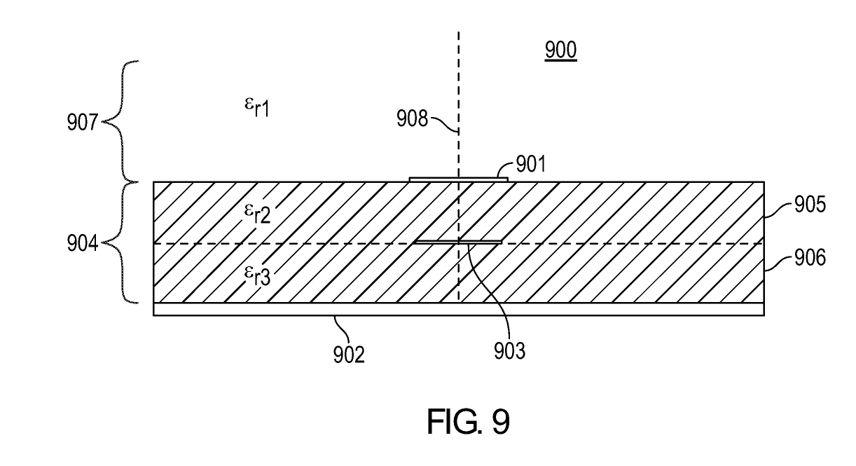

As will become clearer as the present description continues, the lowest order (and desired mode) of the transmission lines of the representative embodiments is a “substantially” TEM mode. To this end, a TEM mode is somewhat of an idealization that follows from the solutions to Maxwell's Equations. In reality, at any nonzero frequency, the “TEM mode” actually has small deviations from a purely transverse electric field due to the imperfect nature of the conductors of the transmission line. Also, inhomogeneity in the dielectric region(s) (e.g., comprising first and second dielectric layers 905, 906 as depicted in FIG. 9) will lead to dispersion and deviation from the behavior of an ‘ideal’ TEM mode (which is technically dispersionless) in coaxial transmission lines, stripline, etc. at higher frequencies. As such, the term “substantially TEM” mode accounts for such deviations from the ideal behavior due to the environment of the transmission lines of the representative embodiments described below.

The present teachings are described initially in connection with representative embodiments that comprise a coaxial transmission line (or, variously coaxial cable). As will be appreciated as the present description continues, the comparatively symmetrical structure of the coaxial transmission line enables the description of various salient features of the present teachings in a comparatively straight-forward manner. However, it is emphasized that the present teachings are not limited to representative embodiments comprising coaxial transmission lines. Rather, and as described more fully below, the present teachings are contemplated for use in other types of transmission lines to include transmission lines with an inner conductor that is geometrically offset relative to an outer conductor, stripline transmission lines, and microstrip transmission lines, which are transmitting substantially TEM modes. Moreover, the present teachings are contemplated for devices used to effect connections between a transmission line and an electrical device, or other transmission line (e.g., electrical connectors, adapters, attenuators, etc.). By way of example, the ends of coaxial transmission line may terminate at a coaxial electrical connector (not show) that is designed to maintain a coaxial form across the connection and have substantially the same impedance as the coaxial transmission line to reduce reflections back into the coaxial transmission line. Connectors are usually plated with high-conductivity metals such as silver or tarnish-resistant gold.

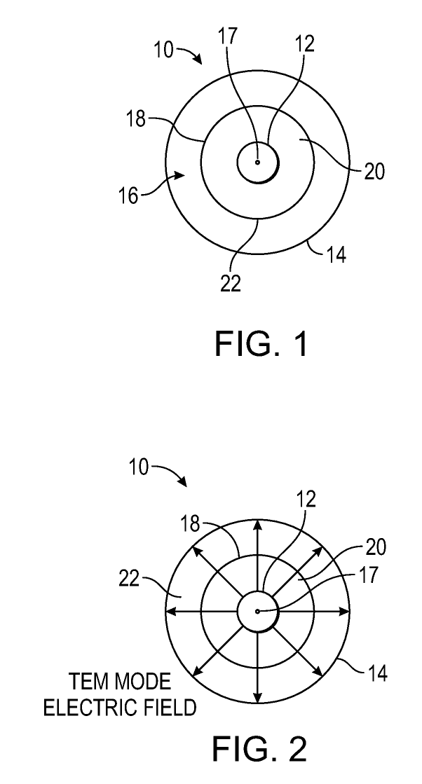

Referring now to FIGS. 1-3, a coaxial transmission line 10 in accordance with a representative embodiment will now be described. The coaxial transmission line 10 is shown in the drawings as a coaxial cable, for example. The coaxial transmission line 10 includes an inner electrical conductor 12 (sometimes referred to as a first electrical conductor), an outer electrical conductor 14 (sometimes referred to as a second electrical conductor), a dielectric region 16 between the inner electrical conductor 12 and the outer electrical conductor 14, and an electrically thin resistive layer 18 within the dielectric region 16 and concentric with the inner electrical conductor 12 and the outer electrical conductor 14.

In representative embodiments, the electrically thin resistive layer 18 is continuous and extends along the length of the coaxial transmission line 10. The continuity of the electrically thin resistive layer 18 is common to the transmission lines of other representative embodiments described herein. Alternatively, the electrically thin resistive layer 18, as well the electrically thin resistive layer of other representative embodiments may be discontinuous, thereby having gaps along the length of the particular transmission line.

The inner electrical conductor 12 has a common propagation axis 17 with the outer electrical conductor 14. Similarly, the inner electrical conductor 12 and the outer electrical conductor 14 share a common geometric center (e.g., a point on the common propagation axis 17). Moreover, the coaxial transmission line 10 is substantially circular in cross-section. Generally, the term ‘coaxial’ means the various layers/regions of a transmission line have a common propagation axis. Likewise the term ‘concentric’ means layers/regions of a transmission line have the same geometric center. As will be appreciated as the present description continues, the transmission lines of some representative embodiments are coaxial and concentric, whereas in other representative embodiments the transmission lines are not concentric. Finally, the transmission lines of the representative embodiments are not limited to those circular in cross-section. Rather, transmission lines with other cross-sections are contemplated, including but not limited to, rectangular and elliptical cross-sections.

As may be appreciated by those skilled in the art, the inner electrical conductor 12 and the outer electrical conductor 14 may be any suitable electrical conductor such as a copper wire, or other metal, metal alloy, or non-metal electrical conductor. The dielectric materials or layers contemplated for use in dielectric region 16 include, but are not limited to glass fiber material, plastics such as polytetrafluoroethylene (PTFE), low-k dielectric material with a reduced loss tangent (e.g., 10⁻²), ceramic materials, liquid crystal polymer (LCP), or any other suitable dielectric material, including air, and combinations thereof. A protective sheath can include a protective plastic coating or other suitable protective material, and is preferably a non-conductive insulating sleeve. In representative embodiments described below, the dielectric region 16 may comprise one or more dielectric layers. Notably, the number of dielectric layers described in the various representative embodiments is generally illustrative, and more (than one) or fewer layers are contemplated. However, generally the dielectric constants of the various dielectric layers are substantially the same in order to support substantially TEM modes of propagation.

The coaxial transmission line 10 differs from other shielded cables used for carrying lower-frequency signals, such as audio signals, in that the dimensions of the coaxial transmission line 10 are controlled to give a substantially precise, substantially constant spacing between the inner electrical conductor 12 and the outer electrical conductor 14.

Coaxial transmission line 10 is often used as a transmission line for radio frequency signals. Applications of coaxial transmission line 10 include feedlines connecting radio transmitters and receivers with their antennas, computer network (Internet) connections, and distributing cable television signals. In radio-frequency applications, the electric and magnetic signals propagate primarily in the substantially transverse electric magnetic (TEM) mode, which is the single desired mode to be supported by the transmission line. In a substantially TEM mode, the electric and magnetic fields are both substantially perpendicular to the direction of propagation. However, above a certain cutoff frequency, transverse electric (TE) or transverse magnetic (TM) modes, or both, can also propagate, as they do in a waveguide. It is usually undesirable to transmit signals above the cutoff frequency, since it may cause multiple modes with different phase velocities to propagate, interfering with each other. The average of the circumference between the inner electrical conductor 12 and the inside of the outer electrical conductor 14 is roughly inversely proportional to the cutoff frequency.

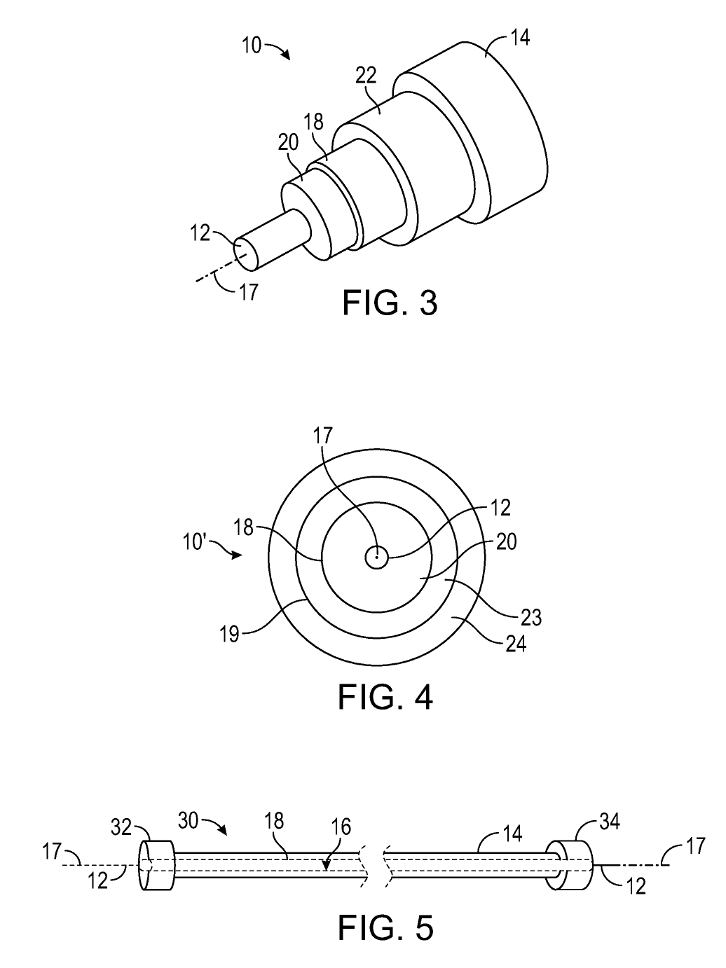

As illustrated in FIGS. 2 and 3, the electrically thin resistive layer 18 is an electrically resistive layer selected and configured, as described below, to be substantially transparent to a substantially transverse-electromagnetic (TEM) mode of transmission, while substantially completely attenuating higher order modes of transmission. Generally, substantially completely attenuating means the coaxial transmission line 10, or other transmission line according to representative embodiments described herein, is designed to accommodate a predetermined threshold of relative attenuation between the desired substantially TEM mode and the undesired higher order modes. As will be appreciated, among other design considerations, this predetermined threshold is realized through the selection of the appropriate thickness (e.g., via the skin depth described below) and resistivity of the electrically thin resistive layer 18. For example, in an application where RF frequencies up to 10² GHz are relevant and the transmission length is on the order of 10¹ cm, the threshold of relative attenuation requires a TEM attenuation constant of approximately 0.1 m⁻¹, but attenuation of the higher order modes by more than approximately 100 m⁻¹, and usefully over approximately 1000 m⁻¹ are contemplated. On the other hand, in an application where the highest frequency of operation is only a few GHz (or less) and the transmission length is tens of meters, the threshold of relative attenuation requires a TEM attenuation constant of approximately 0 m⁻¹ to approximately 0.01 m⁻¹, while attenuating the higher order modes by at least approximately 1.0 m⁻¹, but usefully by more than approximately 10 m⁻¹ are contemplated. It is emphasized that these examples are merely illustrative, and are not intended to be limiting of the present teachings.

As used herein, an “electrically thin” layer is one for which the layer thickness is less than the skin depth δ at the (highest) signal frequency of interest. This insures that the substantially TEM mode is minimally absorbed. The skin depth is given by δ=1/√(πfμσ), where δ is in meters, f is the frequency in Hz, μ is the magnetic permeability of the layer in Henrys/meter, and σ is the conductivity of the layer in Siemens/meter.

So for the discussion herein, if t is the physical thickness of the electrically thin resistive layer 18, it is “electrically thin” if t<δₘᵢₙ=1/√(πfₘₐₓμσ), where δₘᵢₙ is the skin depth calculated at the maximum frequency fₘₐₓ. For example, suppose fₘₐₓ=200 GHz, the layer is nonmagnetic and hence μ=μ₀=the vacuum permeability=4π*10-7 Henrys/meter, and the conductivity is 100 Siemens/meter. Then δₘᵢₙ=112.5 μm, so a resistive layer thickness t of 25 μm would be considered electrically thin in this case. Recapitulating, the electrically thin resistive layer 18 is electrically thin when its thickness is less than a skin depth at a maximum operating frequency of the coaxial transmission line 10.

The dielectric region 16 may comprise an inner dielectric material 20 between the inner electrical conductor 12 and the electrically thin resistive layer 18, and an outer dielectric material 22 between the electrically thin resistive layer 18 and the outer electrical conductor 14. In various embodiments, the inner dielectric material 20 and the outer dielectric material 22 have approximately the same thickness. In some embodiments, a thickness of the inner dielectric material 20 is approximately twice a thickness of the outer dielectric material 22.

The electrically thin resistive layer 18 may be an electrically thin resistive coating on the inner dielectric material 20. The electrically thin resistive layer 18 illustratively includes at least one of TaN, WSiN, resistively-loaded polyimide, graphite, graphene, transition metal dichalcogenide (TMDC), nichrome (NiCr), nickel phosphorus (NiP), indium oxide, and tin oxide. Notably, however, other materials within the purview of one of ordinary skill in the art having the benefit of the present teachings, are contemplated for use as the electrically thin resistive layer 18.

Transition metal dichalcogenides (TMDCs) include: HfSe₂, HfS₂, SnS₂, ZrS₂, MoS₂, MoSe₂, MoTe₂, WS₂, WSe₂, WTe₂, ReS₂, ReSe₂, SnSe₂, SnTe₂, TaS₂, TaSe₂, MoSSe, WSSe, MoWS₂, MoWSe₂, PbSnS₂. The chalcogen family includes the Group VI elements S, Se and Te.

The electrically thin resistive layer 18 may have an electrical sheet resistance between 20-2500 ohms/sq and preferably between 20-200 ohms/sq.

With additional reference to FIG. 4, another embodiment of a coaxial transmission line 10′ will be described. In this embodiment, an additional electrically thin resistive layer 19 is included within the dielectric region and concentric with the inner electrical conductor 12 and the outer electrical conductor 14. In such an embodiment, the dielectric region includes the inner dielectric material 20, a middle dielectric material 23, and an outer dielectric material 24. Such dielectric materials may include the same or different materials. Multiple electrically thin resistive layers may be included based upon desired attenuation characteristics.

Adding a second electrically thin resistive layer, perhaps ⅔ of the way in from the outer electrical conductor 14 may be better positioned to attenuate some higher order modes, and may be beneficial in the presence of multiple discontinuities or with a poorly matched load. It may also be useful to allow a cable to be bent multiple times. So, it may be desired to include the additional electrically thin resistive layer 19 between electrically thin resistive layer 18 and the outer electrical conductor 14. However, the benefits of the additional electrically thin resistive layer 19 must be weighed against the possible disadvantage that the additional electrically thin resistive layer 19 may add some insertion loss for the dominant substantially TEM mode.

With additional reference to FIG. 5, another embodiment is described. Here, the inner electrical conductor 12, outer electrical conductor 14 and dielectric region 16 define a length of coaxial cable 30, with coaxial connectors 32, 34 at opposite ends of the coaxial cable 30. The electrically thin resistive layer 18 extends within the entire length of coaxial cable 30 and within the coaxial connectors 32, 34.

Also, in other embodiments, the inner electrical conductor 12, outer electrical conductor 14 and dielectric region 16 may define a length of micro-coaxial transmission line.

Having set forth the various structures of the exemplary embodiments above, features, advantages and analysis will now be discussed. The example embodiments are directed to a coaxial transmission line 10, 10′, e.g. a coaxial cable 30, in which a concentric electrically thin resistive layer 18 is sandwiched somewhere within the insulating (dielectric) region 16 that separates the inner electrical conductor 12 and outer electrical conductor 14. Namely, in addition to the typical inner and outer electrical conductors 12/14 made out of metals with high conductivity, we now have an inner dielectric and an outer dielectric separated by an electrically thin cylindrical resistive layer 18. All regions, inner electrical conductor 12, inner dielectric material 20, electrically thin cylindrical resistive layer 18, outer dielectric material 22, and outer electrical conductor 14 are concentric. The term coaxial and/or concentric means that the layers/regions have the same axis/center. This is not limited to any particular cross-section. Circular, rectangular and other cross sections are contemplated herein. By way of example, the inner and outer conductors may have other cross-sectional shapes, such as rectangular (described below). Alternatively, the inner and outer conductors may have different cross-sectional shapes (e.g., the inner conductor may be circular in cross-section, and the outer conductor may be rectangular in cross-section). Regardless of the shapes of the inner and outer conductors, the electrically thin resistive layer is selected to have a shape so that the electric field lines of the substantially TEM mode are substantially perpendicular (i.e., substantially parallel to the normal of the electrically thin resistive layer) at each point of incidence, and to be substantially transparent to the substantially TEM mode of transmission, while substantially attenuating higher order modes of transmission.

As in conventional coax, the desired substantially transverse electromagnetic (TEM) features an everywhere substantially radially directed electric field, as shown in FIG. 2. All higher order modes, whether transverse electric (TE) or transverse magnetic (TM), fail to have this property.

In particular, all TM modes have a strong longitudinal (along the axis) component of electric field. These longitudinal electric vectors will generate axial RF currents in the resistive cylinder, leading to high ohmic dissipation of the TM modes. Conversely, the TE modes have pronounced azimuthal (i.e., clockwise or counterclockwise directed about the axis) electric field vectors, which in turn generate local azimuthal currents in the resistive cylinder. Again, since a resistive sheet is not a good electrical conductor, this results in high ohmic dissipation of the TE modes.

The substantially TEM mode, on the other hand, suffers little ohmic dissipation because the thin resistive cylinder does not allow radial currents to flow.

An important advantage of the embodiments of the present teachings is the realization of comparatively larger dimensions for both the inner and outer electrical conductors to be used at higher frequencies. This results in less electrically conductive loss for the desired broadband substantially TEM mode due to reduced current crowding. It also allows the potential use of sturdier connectors and a sturdier cable itself to a given maximum TEM frequency. As opposed to waveguide technology, the present embodiments are still a truly broadband (DC to a very high frequency, e.g. millimeter waves or sub-millimeter waves) conduit.

In practice, the industry likes to deal with 50-ohm cables at millimeter-wave frequencies. The usual dielectric PTFE has a relative dielectric constant of approximately 1.9—the exact value depends on the type of PTFE and the frequency, but this is close enough for this discussion. For this dielectric value in conventional coaxial cable, the ratio of outer electrical conductor ID to inner electrical conductor OD=3.154 to achieve 50Ω characteristic impedance.

An example of a practical frequency extension goal is now discussed. 1.85-mm cable is single-mode up to approximately ˜73 GHz. It would be very useful to extend this frequency almost threefold to 220 GHz, for example. A relevant computation is to identify how many and which TE and TM modes between 73 GHz and 220 GHz have to be attenuated by the resistive cylindrical sheet.

A simple way to do this accounting is to compute the dimensionless eigenvalues k_{c}a for the higher-order modes, where k_{c} is the cutoff wavenumber=2π/λ_{c} and 2a is the outer electrical conductor ID. Here λ_{c} is the free-space cutoff wavelength=c/f_{c}, where f_{c} is the cutoff frequency and c is the speed of light in vacuum. The lowest eigenvalue corresponds to the ˜73 GHz cutoff of the first higher-order mode, which happens to be the TE11 mode. Any eigenvalue within a factor of 3 of the lowest eigenvalue indicates a mode that should be attenuated. Eigenvalues more than a factor of 3 greater than the lowest eigenvalue correspond to modes that are still in cutoff, even at 220 GHz.

The reason for using dimensionless eigenvalues is that the same reasoning can be scaled to other cases. For example, it may be desired to extend the operating frequency of 1-mm cable, which is single-mode to ˜120 GHz, to ˜360 GHz. The lowest eigenvalue then corresponds to the ˜120 GHz cutoff of the TE₁₁ mode in 1-mm cable.

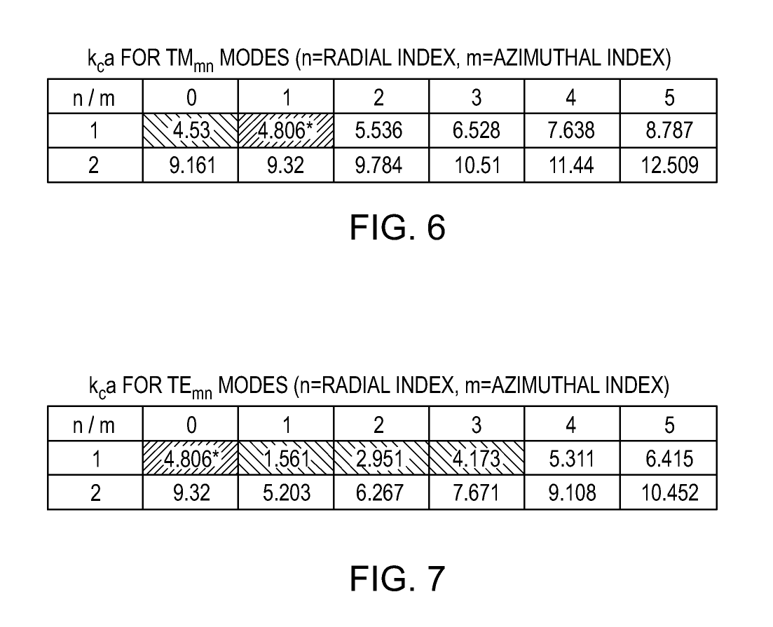

The tables in FIGS. 6 and 7 show the accounting for the TE and TM modes, respectively. In FIG. 6, which shows the eigenvalues of TE modes for a 50-ohm Teflon-filled coax, the eigenvalues at TE₁₁, TE₁₂, and TE₁₃ correspond to modes that should be attenuated. The other eigenvalues are modes still in cutoff except for TE₁₀ which comes close to the arbitrary “thrice 1st cutoff frequency” rule in this example. In other words, TE₁₀ is barely still cutoff at 220 GHz, so resistive attenuation here may be desirable if the maximum operating frequency needs to be pushed just a bit higher.

The table of FIG. 7 shows the eigenvalues of TM modes for a 50-ohm Teflon-filled coax, and it can be seen that there are only a handful of modes to be concerned with resistively attenuating. Beneficially, the sheet resistance and radius of the resistive cylinder can be selected to minimally attenuate the substantially TEM mode while maximally attenuating higher order modes (e.g., the TE₁₁ mode).

Let r be the radius of the resistive cylinder. To keep the discussion generic (as opposed to dealing only with 1.85-mm cable), the designer can hone the sheet resistance and the dimensionless ratio air, where 2a is the inner diameter ID of the outer electrical conductor 14. Sheet resistance in the range of approximately 20 Ω/sq to approximately 200 Ω/sq and air values in the range approximately 1.2 to approximately 2.4 are effective. The resistive cylinder may be substantially midway between the inner electrical conductor 12 and the outer electrical conductor 14.

An example of a way to construct the geometry is to roll a thin resistive sheet around the inner dielectric material 20, already with the inner electrical conductor 12 inside its core. Then the outer dielectric material 22 can be slipped over this partial assembly. Finally the outer electrical conductor 14 can be slipped over on the outside.

Graphite/graphene, MoS2, WS2, and MoSe2 are available in lubricant form, which may lead to an alternative construction method. The inner dielectric material 20 (e.g. a cylinder) can be lubricated with the desired resistive lubricant. The lubrication coating thickness is chosen to produce the desired sheet resistance, depending on the electrical resistivity of the lubricant. The outer dielectric material 22, e.g. initially including two half-cylinders, is then clam-shelled about the lubricated inner dielectric material 20. Finally the outer electrical conductor 14 is slipped over the outer dielectric material 22. With a snug fit, the outer electrical conductor 14, e.g. a cylinder, will hold the half shells in place so no adhesive may even be necessary.

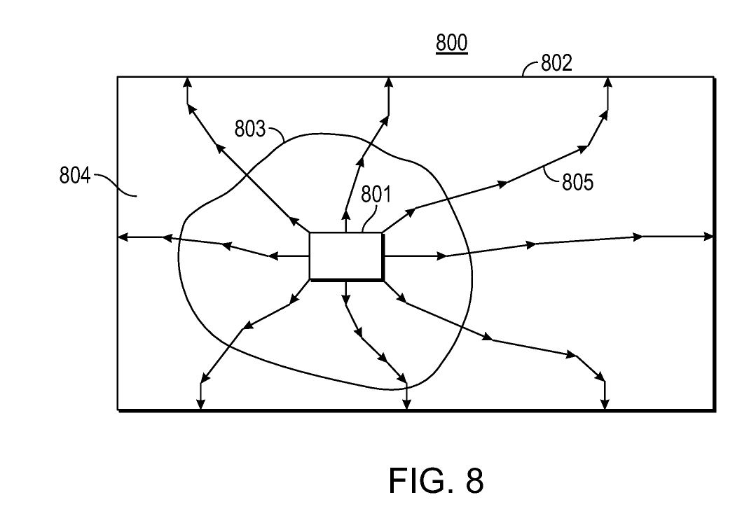

FIG. 8 is a cross-sectional view of a transmission line 800 in accordance with a representative embodiment. Many aspects and details of the transmission line 800 are common to the transmission lines described in connection with the representative embodiments of FIGS. 1-7, above, and may not be repeated in order to avoid obscuring the presently described representative embodiments.

The transmission line 800 comprises a first electrical conductor 801, which functions as a signal line, and a second electrical conductor 802 disposed thereabout, which functions as a ground plane. An electrically thin resistive layer 803 is disposed in a dielectric region 804 and between the first electrical conductor 801 and the second electrical conductor 802. Notably, the dielectric region 804 comprises one or more of the dielectric materials described above. If more than one material is used in the dielectric region 804, their dielectric constants are approximately the same.

The transmission line 800 shows certain features alluded to above, and contemplated by the present teachings. Notably, some of these features may be foregone, with the resulting structure contemplated by the present teachings. The second electrical conductor 802, which is an outer electrical conductor, is neither circular nor elliptical in cross-section. Rather, the second electrical conductor 802 is substantially rectangular. Alternatively, the second electrical conductor 802 could have other cross-sectional shapes, such as square, or polygonal. As can be appreciated, the cross-sectional shape of the second electrical conductor 802, among other things, dictates the supported single mode, in this case a substantially TEM mode, and thus the orientation of the electric field lines. The electrically thin resistive layer 803 has a shape that is selected so that electric field lines 805 of the substantially TEM mode are incident thereon orthogonally (or parallel to the normal to the surface of the electrically thin resistive layer). As in representative embodiments described above in connection with FIGS. 1-7, the electrically thin resistive layer 803 is configured to be substantially transparent to a substantially transverse-electromagnetic (TEM) mode of transmission, while substantially completely attenuating higher order modes of transmission.

The first electrical conductor 801 is offset relative to the second electrical conductor 802, and therefore does not share a common geometric center. This is merely illustrative, and, as noted above, other configurations are contemplated by the present teachings (e.g., the first and second electrical conductors 801, 802 share a common geometric center). Moreover, the first electrical conductor 801 illustratively has a substantially rectangular cross-section. This too is not essential and the first electrical conductor 801 may have other cross-sectional shapes, such as circular or elliptical. As can be appreciated from the present teachings, the selection of the shapes of the various components of the transmission lines impacts the orientation of the electric field lines of the substantially TEM mode. The electrically thin resistive layer 803 is selected to have a shape so that the electric field lines of the substantially TEM mode are substantially perpendicular (i.e., substantially parallel to the normal to the electrically thin resistive layer) at each point of incidence, and to be substantially transparent to the substantially TEM mode of transmission, while substantially attenuating higher order modes of transmission.

FIG. 9 is a cross-sectional view a transmission line 900 in accordance with a representative embodiment. Many aspects and details of the transmission line 900 are common to the transmission lines described in connection with the representative embodiments of FIGS. 1-8, above, and may not be repeated in order to avoid obscuring the presently described representative embodiments.

The transmission line 900 is illustratively a microstrip transmission line, comprising a first electrical conductor 901 (i.e., the signal conductor) and a second electrical conductor 902 (i.e., the ground conductor) disposed below the first electrical conductor 901. An electrically thin resistive layer 903 is disposed in a substrate 904, which comprises a first dielectric layer 905 and a second dielectric layer 906. A superstrate 907 is disposed over the substrate 904. The first and second dielectric layers 905, 906 have dielectric constants εᵣ₂ and εᵣ₃, whereas the superstrate 907 has a dielectric constant εᵣ₁ less than or equal to that of the substrate 904. By way of example, εᵣ₂ is substantially the same as εᵣ₃.

The bisecting plane 908 of the first electrical conductor 901 also bisects the electrically thin resistive layer 903. The most intense electric fields occur in the bisecting plane 908, and, as such, hence it is useful that the electrically thin resistive layer 903 be perpendicular to the bisecting plane 908. Also, for most effective attenuation of potentially interfering higher order modes, the electrically thin resistive layer 903 is best situated symmetrically about the bisecting plane 908.

The electrically thin resistive layer 903 is selected to have a shape and orientation so that the electric field lines (not shown) of the desired substantially TEM mode are substantially perpendicular (i.e., parallel to the normal to the electrically thin resistive layer) at each point of incidence, and to be substantially transparent to the substantially TEM mode of transmission, while substantially attenuating higher order modes of transmission.

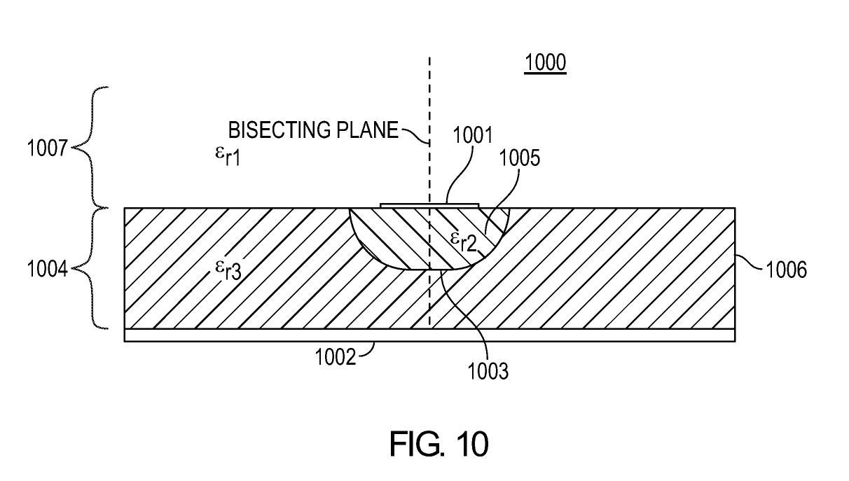

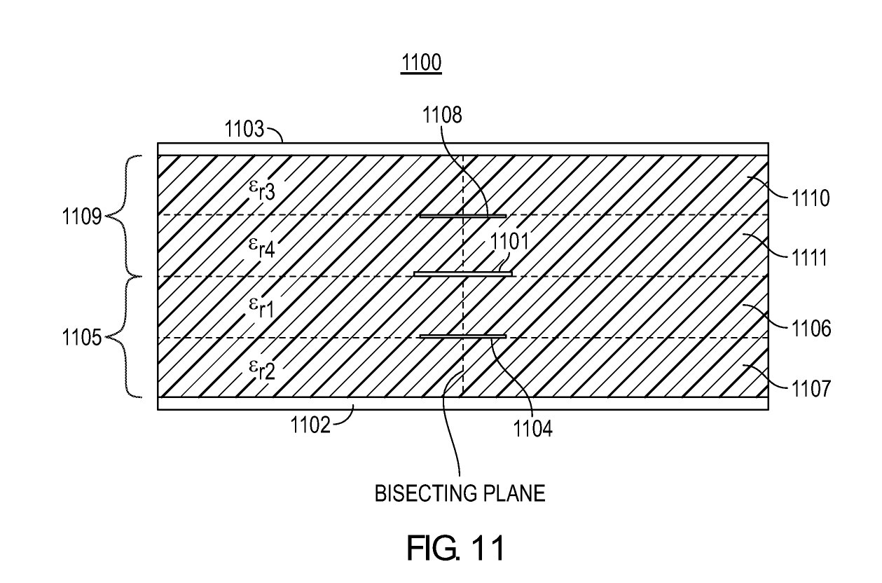

FIG. 10 is a cross-sectional view of a transmission line 1000 in accordance with a representative embodiment. Many aspects and details of the transmission line 1000 are common to the transmission lines described in connection with the representative embodiments of FIGS. 1-9, above, and may not be repeated in order to avoid obscuring the presently described representative embodiments.

The transmission line 1000 is illustratively a microstrip transmission line, comprising a first electrical conductor 1001 (i.e., the signal conductor) and a second electrical conductor 1002 (i.e., the ground conductor) disposed below the first electrical conductor 1001. An electrically thin resistive layer 1003 is disposed in a substrate 1004, which comprises a first dielectric layer 1005 and a second dielectric layer 1006. A superstrate 1007 is disposed over the substrate 1004. The first and second dielectric layers 1005, 1006 have dielectric constants εᵣ₂ and εᵣ₃, whereas the superstrate 1007 has a dielectric constant εᵣ₁ less than or equal to that of the substrate 1004. By way of example, εᵣ₂ is substantially the same as εᵣ₃.

The electrically thin resistive layer 1003 is selected to have a shape and orientation so that the electric field lines (not shown) of the substantially TEM mode are substantially perpendicular (i.e., substantially parallel to the normal to the electrically thin resistive layer) at each point of incidence, and to be substantially transparent to the substantially TEM mode of transmission, while substantially attenuating higher order modes of transmission. Notably, and unlike the electrically thin resistive layer 903, electrically thin resistive layer 1003 is curved to follow a magnetic field line contour of the substantially TEM mode all the way to the interface between the substrate 1004 and the superstrate 1007. As will be appreciated by one of ordinary skill in the art, in a substantially TEM mode the electric and magnetic field lines are substantially mutually perpendicular, and their cross product vector (i.e., the Poynting Vector) points in the propagation direction. Hence, if the resistive sheet follows a magnetic field contour, it is automatically everywhere-perpendicular to the electric field.

One benefit of the transmission line 1000 is its greater damping of the higher order modes because of the electrically thin resistive layer 1003 that is oriented relative to the B-field lines of the higher order modes.

FIG. 11 is a cross-sectional view of a transmission line 1100 in accordance with a representative embodiment. Many aspects and details of the transmission line 1100 are common to the transmission lines described in connection with the representative embodiments of FIGS. 1-10, above, and may not be repeated in order to avoid obscuring the presently described representative embodiments.

The transmission line 1100 is illustratively a stripline transmission line, comprising a first electrical conductor 1101 (i.e., the signal conductor), a second electrical conductor 1102 (i.e., the lower ground conductor) disposed below the first electrical conductor 1101, and a third electrical conductor 1103 (i.e., the upper ground conductor). As is known, ground-to-ground vias (not shown) may be used to ensure the second and third electrical conductors 1102, 1103 are maintained at the same electrical potential.

A first electrically thin resistive layer 1104 is disposed beneath the first electrical conductor 1101 in a substrate 1105, which comprises a first dielectric layer 1106 and a second dielectric layer 1107. A second electrically thin resistive layer 1108 is disposed above the first electrical conductor 1101 in a superstrate 1109, which comprises a third dielectric layer 1110 and a fourth dielectric layer 1111. The first˜fourth dielectric layers 1106, 1107, 1110, 1111, respectively have dielectric constants εᵣ₁, εᵣ₂, εᵣ₃ and εᵣ₄, respectively.

In accordance with a representative embodiment, the dielectric constants of the first˜fourth dielectric layers 1106, 1107, 1110, 1111 are substantially the same, hence the lowest order mode of propagation is substantially TEM.

The first and second electrically thin resistive layers 1104, 1108 are selected to have a shape and orientation so that the electric field lines (not shown) of the substantially TEM mode are substantially perpendicular (i.e., substantially parallel to the normal to the electrically thin resistive layer) at each point of incidence, and to be substantially transparent to the substantially TEM mode of transmission, while substantially attenuating higher order modes of transmission.

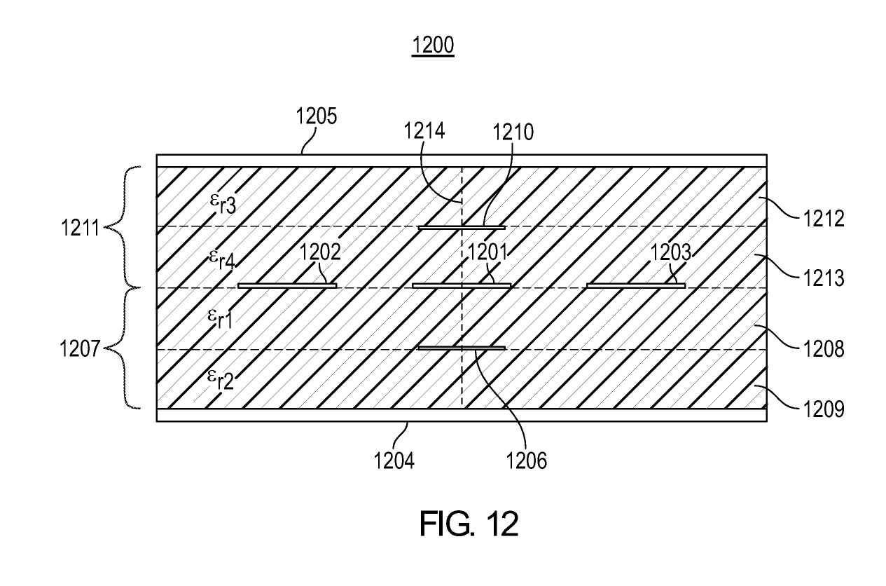

FIG. 12 is a cross-sectional view of a transmission line 1200 in accordance with a representative embodiment. Many aspects and details of the transmission line 1200 are common to the transmission lines described in connection with the representative embodiments of FIGS. 1-11, above, and may not be repeated in order to avoid obscuring the presently described representative embodiments.

The transmission line 1200 is illustratively a stripline transmission line, comprising a first electrical conductor 1201 (i.e., the signal conductor), a second electrical conductor 1202 (i.e., a first coplanar ground conductor) disposed adjacent to the first electrical conductor 1201, and a third electrical conductor 1203 (i.e., a second coplanar ground conductor).

A second electrical conductor 1204 (i.e., the lower ground conductor) is disposed below the first electrical conductor 1201, and a fifth electrical conductor 1205 (i.e., the upper ground conductor) is disposed above the first electrical conductor 1201. As noted above, ground-to-ground vias (not shown) may be used to ensure the second˜fifth electrical conductors 1202˜1205 are maintained at the same electrical potential.

A first electrically thin resistive layer 1206 is disposed beneath the first electrical conductor 1201 in a substrate 1207, which comprises a first dielectric layer 1208 and a second dielectric layer 1209. A second electrically thin resistive layer 1210 is disposed above the first electrical conductor 1201 in a superstrate 1211, which comprises a third dielectric layer 1212 and a fourth dielectric layer 1213. The first˜fourth dielectric layers 1208, 1209, 1212, 1213, respectively, have dielectric constants εᵣ₁, εᵣ₂, εᵣ₃ and εᵣ₂, respectively.

In accordance with a representative embodiment, the dielectric constants of the first˜fourth dielectric layers 1208, 1209, 1212, 1213 are substantially the same, hence the lowest order mode of propagation is substantially TEM.

The first and second electrically thin resistive layers 1206, 1210 are selected to have a shape and orientation so that the electric field lines (not shown) of the substantially TEM mode are substantially perpendicular (i.e., substantially parallel to the normal to the electrically thin resistive layer) at each point of incidence, and to be substantially transparent to the substantially TEM mode of transmission, while substantially attenuating higher order modes of transmission.

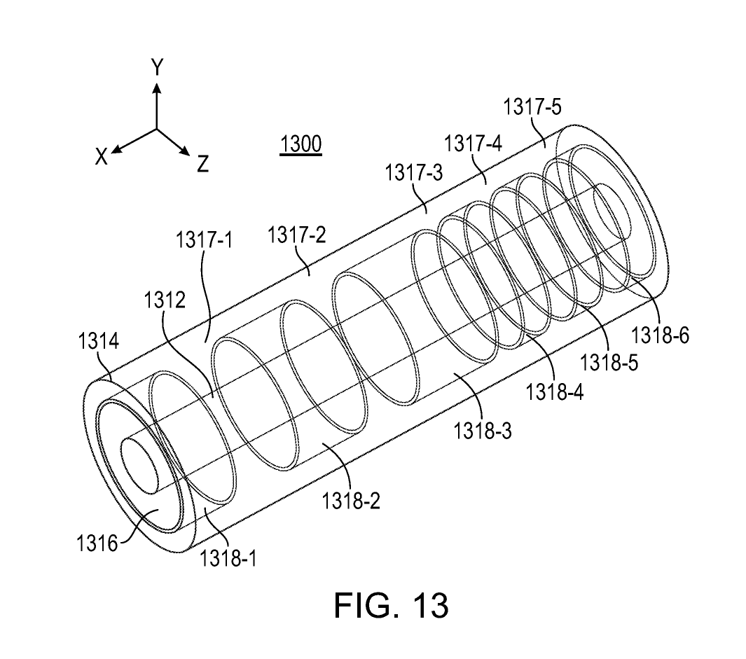

FIG. 13 is a perspective view of a coaxial transmission line 1300 in accordance with a representative embodiment. The coaxial transmission line 1300 of FIG. 13 is useful in illustrating a discontinuous electrically thin resistive layer in accordance with representative embodiments, with sections of the electrically thin resistive layer, or of the gaps therebetween, or both, having the same or differing lengths. As will be appreciated as the present description continues, while the inclusion of the electrically thin resistive sheet provides useful improvements to signal transmission as described above, to some extent it is beneficial to minimize the area of the electrically thin resistive layer provided in the signal transmission line using a gap. To this end, while the electrically thin resistive layer beneficially attenuates power of higher order modes, because of non-idealities or unavoidable transitions the electrically thin resistive layer does attenuate the desired TEM mode, and thus does increase the TEM insertion loss. In the following illustrative embodiments, illustrative configurations of the electrically thin resistive layer are useful in addressing challenges of improving TEM insertion loss, while attenuating higher order modes.

The coaxial transmission line 1300 includes an inner electrical conductor 1312 (sometimes referred to as a first electrical conductor), an outer electrical conductor 1314 (sometimes referred to as a second electrical conductor), a dielectric region 1316 between the inner electrical conductor 1312 and the outer electrical conductor 1314, and first through sixth sections 1318-1˜1318-6 of an electrically thin resistive layer within the dielectric region 1316 and concentric with the inner electrical conductor 1312 and the outer electrical conductor 1314. As such, in accordance with certain representative embodiments, the electrically thin resistive layer is not continuous, but rather has gaps along the length of the coaxial transmission line 1300. In the illustrative configuration of FIG. 13, there are first through fifth gaps 1317-1˜1317-5 between respective first through fifth sections 1318-1˜1318-6 of the electrically thin resistive layer. Notably, the number of sections and the number of gaps depicted in FIG. 13 is merely illustrative, and more or fewer sections and gaps are contemplated.

As shown in FIG. 13, each of the first through sixth sections 1318-1˜1318-6 of the electrically thin resistive layer, and each of the first through fifth gaps 1317-1˜1317-5 have a length along the z direction of the coordinate system depicted in FIG. 3. As depicted, the first through sixth sections 1318-1˜1318-6 may have substantially the same length (e.g., fourth and fifth sections 1318-4 and 1318-5), or may have different lengths (e.g., first section 1318-1 and fourth section 1318-4). Similarly, the first through fifth gaps 1317-1˜1317-5 may have the same length (e.g., 1317-4 and 1317-5), or may have different lengths (e.g., first 1317-1 and fifth 1317-5). As will be described in accordance with representative embodiments, and as can be empirically determined based on the present teachings, and among other benefits, the ability to tailor the lengths of the first through fifth sections 1318-1˜1318-5, and the lengths of the first through fifth gaps 1317-1˜1317-5 enables the fabrication of coaxial transmission lines that address various common situations experienced in the use of such transmission lines.

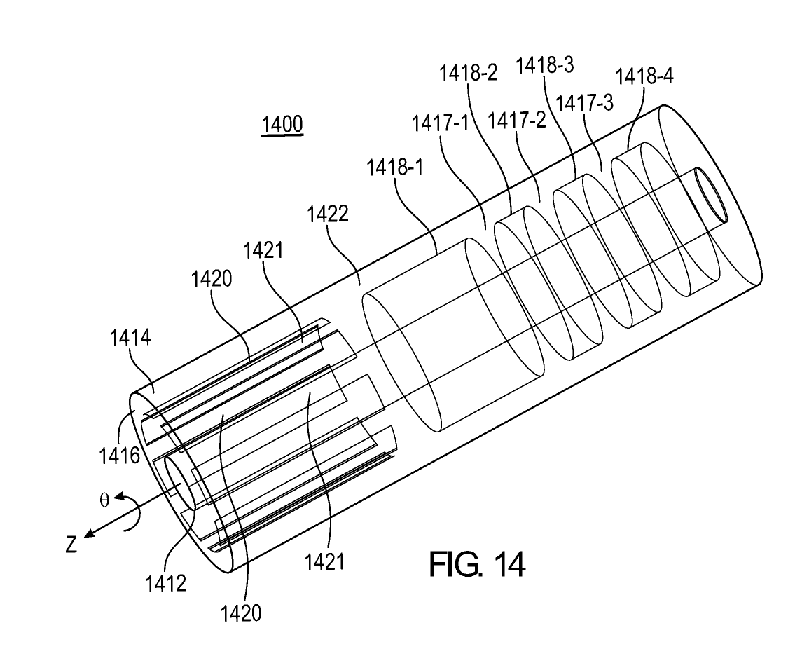

FIG. 14 is a perspective view of a coaxial transmission line 1400 in accordance with a representative embodiment. The coaxial transmission line 1400 of FIG. 14 is useful in illustrating a discontinuous electrically thin resistive layer in accordance with representative embodiments, with sections of the electrically thin resistive layer, and of the gaps therebetween, having the same or differing lengths. As will be appreciated as the present description continues, the variety of configurations of the electrically thin resistive layer is useful in addressing challenges of improving TEM insertion loss, while attenuating higher order modes.

The coaxial transmission line 1400 comprises an inner electrical conductor 1412 (sometimes referred to as a first electrical conductor), an outer electrical conductor 1414 (sometimes referred to as a second electrical conductor), a dielectric region 1416 between the inner electrical conductor 1412 and the outer electrical conductor 1414, and first through fourth sections 1418-1˜1418-4 of an electrically thin resistive layer within the dielectric region 1416 and concentric with the inner electrical conductor 1412 and the outer electrical conductor 1414. As such, in certain representative embodiments, the electrically thin resistive layer is not continuous, but rather has gaps along the length of the coaxial transmission line 1400. In the illustrative configuration of FIG. 14, there are first through third gaps 1417-1˜1417-3 between respective first through fourth sections 1418-1˜1418-4 of the electrically thin resistive layer. As depicted in FIG. 14, the first through third gaps 1417-1˜1417-3 are disposed along a perimeter of respective ones of the first through fourth sections 1418-1˜1418-4. As such, first through third gaps 1417-1˜1417-3 exist perimetrically in the electrically thin resistive layer. Alternatively, the configuration of the first through third gaps 1417-1˜1417-3 can be referred to as being disposed longitudinally along a length of the electrically thin resistive layer, where, as described below, the length is in the z-direction according to the coordinate system of FIG. 14.

The coaxial transmission line also comprises sections 1420 of the electrically thin resistive layer, each spaced from the next by a respective one of a plurality of gaps 1421. Notably, the number of sections and the number of gaps depicted in FIG. 14 is merely illustrative, and more or fewer sections and gaps are contemplated. (Notably, only two sections 1421 and two gaps are delineated in FIG. 14 to avoid obscuring the present description.)

As depicted in FIG. 14, the gaps 1421 exist around the perimeter (i.e., perimetrically) in the electrically thin resistive layer 1420. To this end, rotation around Θ depicted in FIG. 14, alternating gaps 1421 and sections 1420 are traversed. As noted above, like the longitudinal gaps (first through third gaps 1417-1˜1417-3), the alternating gaps 1421 reduce the overall area of the electrically resistive layer of which sections 1420 are comprised. As such, it is possible to attenuate power of higher order modes, while reducing attendant attenuation of the desired TEM mode.

As shown in FIG. 14, each of the first through fourth sections 1418-1˜1418-4 of the electrically thin resistive layer, and each of the first through third gaps 1417-1˜1417-3 have a length along the z direction of the coordinate system depicted in FIG. 14. As depicted, the first through fourth sections 1418-1˜1418-4 may have substantially the same length (e.g., third and fourth sections 1418-3 and 1418-4), or may have different lengths (e.g., first section 1418-1 and fourth section 1418-4). Similarly, the first through third gaps 1417-1˜1417-3 may have the same length (e.g., first and second gaps 1417-1 and 1417-2), or may have different lengths.

Similarly, the widths (measured by rotation around z by Θ) of the sections 1420 may be the same, or the sections 1420 may have differing widths, or a combination thereof. Similarly, the lengths (z-direction of the coordinate system depicted in FIG. 14) of the sections 1420 may be the same, or the sections 1420 may have differing widths, or a combination thereof.

As will be described in accordance with representative embodiments, and as can be empirically determined based on the present teachings, and among other benefits, the ability to tailor the widths of the sections 1420, and the widths of the 1421 enables the fabrication of coaxial transmission lines that address various common situations experienced in the use of such transmission lines.

A variation of the embodiments of the present teachings is to omit (i.e., to provide a gap) providing the electrically thin resistive layer in the “perturbed” lengths of the coaxial cable. That is, in the truly straight sections of a coaxial reach, all the modes are orthogonal so they do not couple to each other. It is only where the ideal coaxial cable is perturbed, e.g., at connectors and in bends, that the modes are deformed from their textbook distributions and cross-coupling can occur. These perturbations can alter the orthogonal relationship of the electric field lines of the substantially TEM mode relative to the electrically thin resistive layer. As such, the electric field lines of the TEM mode are no longer substantially perpendicular (i.e., not substantially parallel to the normal to the electrically thin resistive layer) at each point of incidence. Thereby, TEM modes can occur inducing TEM currents in the electrically thin resistive layer and causing undesired insertion loss. TEM insertion loss will also increase if cable bending radially displaces the resistive sheet or center conductor with respect to each other or to the outer conductor. As described more fully below, in certain representative embodiments, it is useful to provide gaps selectively in the electrically thin resistive layer in regions of the coaxial transmission line where bends occur in order to avoid TEM insertion loss.

Alternatively, in certain representative embodiments the electrically thin resistive layer is disposed only in the “non-perturbed sections” of coaxial cable to avoid its being undesirably displaced in areas of bends in the coaxial cable, which can cause undesirable higher TEM loss. However, for tight bends adequate to suppress higher order modes requires the electrically thin resistive layer be disposed in the perturbed (bend) areas, at the cost of a possible increase in TEM loss. As can be appreciated a trade-off exists, and the inclusion of the electrically thin resistive sheet can be empirically determined based on the present teachings.

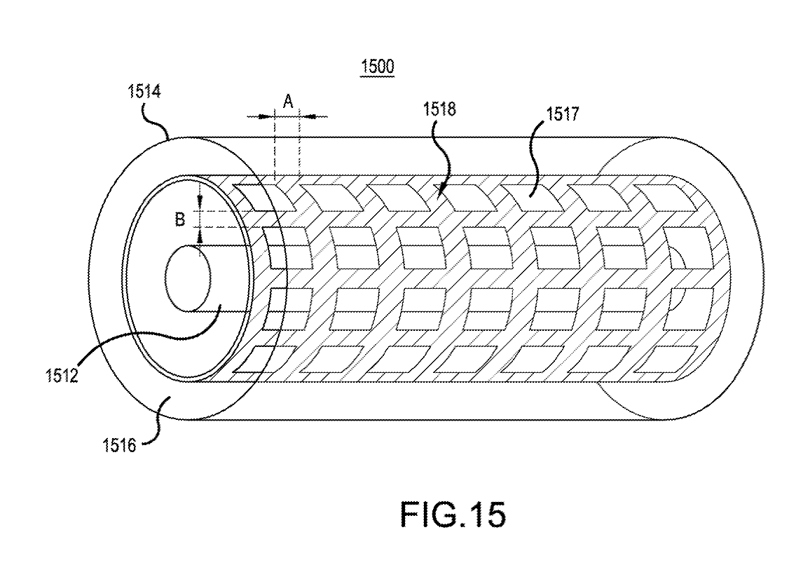

FIG. 15 is a perspective view of a coaxial transmission line 1500 in accordance with a representative embodiment. The coaxial transmission line 1400 of FIG. 14 is useful in illustrating a discontinuous electrically thin resistive layer in accordance with representative embodiments, with sections of the electrically thin resistive layer, and of the gaps therebetween, having the same or differing lengths. As will be appreciated as the present description continues, the variety of configurations of the electrically thin resistive layer is useful in addressing challenges of improving TEM insertion loss, while attenuating higher order modes.

The coaxial transmission line 1500 comprises an inner electrical conductor 1512 (sometimes referred to as a first electrical conductor), an outer electrical conductor 1514 (sometimes referred to as a second electrical conductor), a dielectric region 1516 between the inner electrical conductor 1512 and the outer electrical conductor 1514, and an electrically thin resistive layer 1518 within the dielectric region 1516 and concentric with the inner electrical conductor 1512 and the outer electrical conductor 1514. Gaps 1517 are provided in the electrically thin resistive layer 1518. The gaps 1517 may have substantially the same area, or may have different areal dimensions.

The gaps 1517 are separated by a longitudinal spacing “A” and a radial spacing “B” as depicted in FIG. 15, which provides a “checkerboard” electrically thin resistive layer. Having the electrically thin resistive layer 1518 of this configuration beneficially allows for a trade-off between the TE mode attenuation and TM mode attenuation with respect to TEM attenuation. The amount of resistive sheet material disposed radially around the coaxial transmission line is governed by the magnitude of the radial spacing A. The magnitude of the radial spacing A can be adjusted to attenuate TE modes. By contrast, the amount of resistive sheet material longitudinally along coaxial transmission line 1500 is governed by the magnitude of the longitudinal spacing B. The magnitude of the longitudinal spacing B can be adjusted to attenuate TM modes. Because of non-ideal, real-world effects, the electrically thin resistive layer 1518 can also attenuate the desired TEM mode. Thus, it is desirable to use only as much resistive material (in either the longitudinal direction, or the radial dimension) as is needed to attenuate higher order modes. Again, the magnitudes of the radial spacing A, and the longitudinal spacing B can be determined empirically, based on the present teachings. Just by way of example, in a particular application, if TM mode suppression is not needed, then the longitudinal spacing B would be set to zero in order to minimize TEM insertion loss. Similarly, in a particular application, if TE mode suppression is not needed, then the radial spacing A would be set to zero in order to minimize TEM insertion loss.

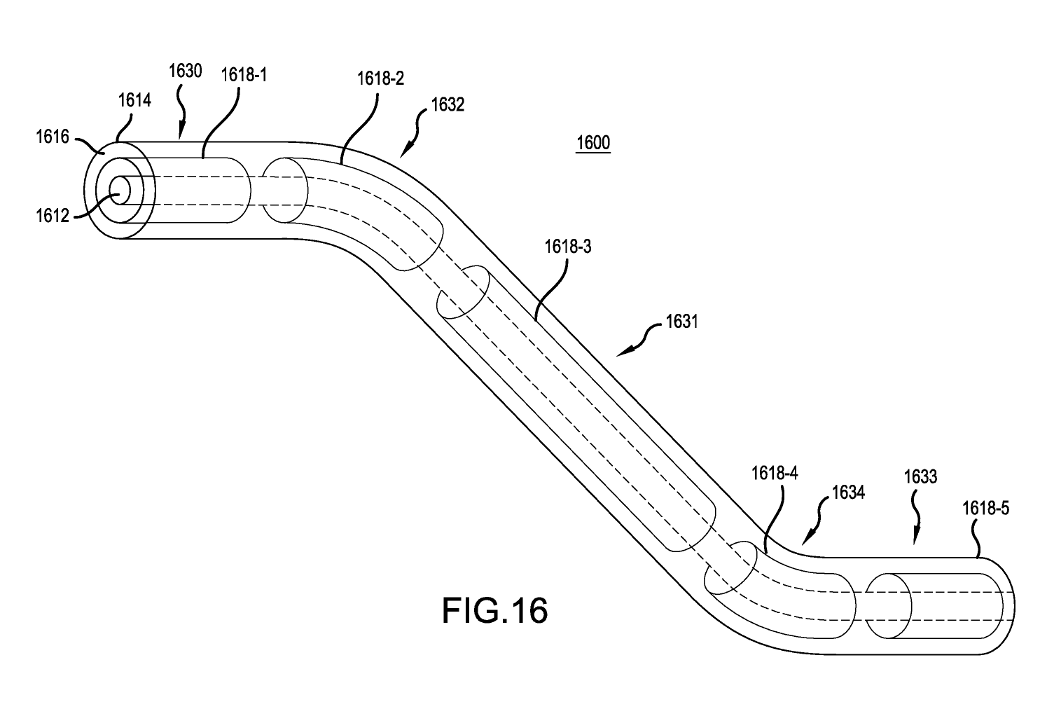

FIG. 16 is a perspective view of a coaxial transmission line 1600 in accordance with a representative embodiment. Often, aspects and details of the coaxial transmission line 1600 are common to those of the representative embodiments described above. These aspects and details may not be repeated in order to avoid obscuring the description of the presently described representative embodiments.

The coaxial transmission line 1600 comprises an inner electrical conductor 1612 (sometimes referred to as a first electrical conductor), an outer electrical conductor 1614 (sometimes referred to as a second electrical conductor), a dielectric region 1616 between the inner electrical conductor 1612 and the outer electrical conductor 1614, and first through fifth sections 1618-1˜1618-5 of an electrically thin resistive layer within the dielectric region 1616 and concentric with the inner electrical conductor 1612 and the outer electrical conductor 1614.

The coaxial transmission line 1600 has a first end 1630, a middle 1631 and a second end 1633. A first bend 1632 is disposed between the first end 1630 and the middle 1631, and a second bend 1634 is disposed between the middle 1631 and the second end 1633.

The first section 1618-1 of the electrically thin resistive layer is disposed at the first end 1630, the second section 1618-2 is disposed at the first bend 1632, the third section 1618-3 is disposed at the middle 1631, the fourth section 1618-4 is disposed at the second bend 1634, and the fifth section 1618-5 is disposed at the second end 1633. As shown, a gap is provided between each of the first through fifth sections 1618-1˜1618-5. Notably, one or more of the first through fifth sections 1618-1˜1618-5 may comprise a single section of the electrically thin resistive layer (i.e., no gaps in the section). Alternatively, one or more of the first through fifth sections 1618-1˜1618-5 may comprise a plurality of sections with gaps (not shown in FIG. 16). This plurality of sections and gaps may be as described above in connection with the representative embodiments of FIGS. 13 and 14. As noted above, this plurality of gaps (not shown in FIG. 16) may serve to reduce the overall area of the electrically thin resistive layer in an effort to attenuate power of higher order modes, while reducing attenuation of the desired TEM mode. Moreover, and as described more fully below, the second and fourth sections 1618-2, 1618-4, disposed in the first and second bends 1632 and 1634, respectively, may be omitted.

The first section 1618-1, the third section 1618-3, and the fifth section 1618-5 are comparatively straight, and do not have the offset of the inner electrical conductor 1612 (and thus loss of symmetry) that can contribute to increased insertion loss.

As noted above, eliminating the electrically thin resistive layer in first and second bends 1632 and 1634 reduces the attenuation of the desired TEM mode, and thus reduces the TEM insertion loss due to the first and second bends 1632 and 1634. However, eliminating the electrically thin resistive layer will reduce the attenuation of higher order modes. As such, a trade-off has to be made in an effort to reduce the TEM insertion loss with an acceptable level in higher order mode energy in the coaxial transmission line. As such, in accordance with a representative embodiment, the elimination of the first and fourth sections 1618-1 and 1618-4 provides comparatively low TEM insertion loss, while providing ample attenuation of higher order modes. However, in such a representative embodiment, the severity of the first and second bends 1632 and 1634 is limited to an Euler bend, such as described commonly owned-copending U.S. patent application No. (Attorney Docket No. 20170505-01) entitled “Bendable Coaxial Transmission Line, Including Electrically Thin Resistive Layer” and filed concurrently herewith. The entire disclosure of U.S. patent application No. (Attorney Docket No. 20170505-01) is specifically incorporated herein by reference. Notably, as can be determined empirically, based on the present teachings, if the severity of the first and second bends 1632 and 1634 is too great, the energy of higher order modes can reach unacceptable values and interfere with the desired TEM mode.

Notably first end 1630, middle 1631, and second end 1633 of the coaxial transmission line 1600 may have “gentle” bends (i.e., comparatively large radii, Euler bends, in keeping with the teachings of above-incorporated U.S. patent application No. (Attorney Docket No. 20170505-01)). In such embodiments, first section 1618-1, the third section 1618-3, and the fifth section 1618-5 may provide sufficient mode suppression for “gentle” bends. Beneficially, first section 1618-1, the third section 1618-3, and the fifth section 1618-5 are sufficiently separated from the first and second bends 1631, 1633, so that bend deformation and non-concentricities of the coaxial transmission will not cause unacceptable TEM insertion loss. The lengths of the first section 1618-1, the third section 1618-3, and the fifth section 1618-5, and the severity of any bend in any of first end 1630, middle 1631, and second end 1633 of the coaxial transmission line 1600 can be determined empirically, based on the present teachings.

By contrast, in regions where comparatively severe (e.g., tight radius, non-Euler bends) bends occur in the coaxial cable 1600, the electrically thin resistive layer of the present teachings provides sufficient attenuation of higher order modes, while maintaining the TEM insertion loss to an acceptable level. As such, in representative embodiments where the first and second bends 1632 and 1634 are comparatively severe (again, tight radius, non-Euler bends), the second and fourth sections 1618-2 and 1618-4 have been found to provide sufficient attenuation of higher order modes, while maintaining the TEM insertion loss to an acceptable level. As noted above, the severity of the first and second bends 1632 and 1634 may be determined empirically, based on the present teachings, to realize acceptable attenuation of higher order modes, while maintaining the TEM insertion loss to an acceptable level.

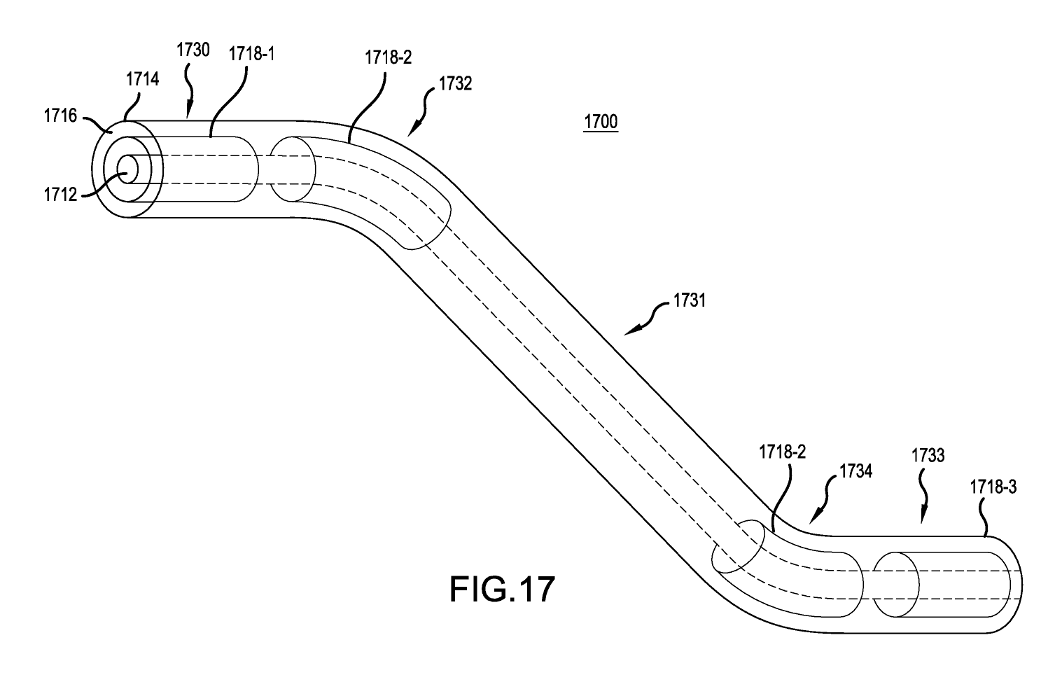

FIG. 17 is a perspective view of a coaxial transmission line 1700 in accordance with a representative embodiment. Often, aspects and details of the coaxial transmission line 1700 are common to those of the representative embodiments described above. These aspects and details may not be repeated in order to avoid obscuring the description of the presently described representative embodiments.

The coaxial transmission line 1700 comprises an inner electrical conductor 1712 (sometimes referred to as a first electrical conductor), an outer electrical conductor 1714 (sometimes referred to as a second electrical conductor), a dielectric region 1716 between the inner electrical conductor 1712 and the outer electrical conductor 1714, and first through fourth sections 1718-1˜1718-4 of an electrically thin resistive layer within the dielectric region 1716 and concentric with the inner electrical conductor 1712 and the outer electrical conductor 1714.

The coaxial transmission line 1700 has a first end 1730, a middle 1731 and a second end 1733. A first bend 1732 is disposed between the first end 1730 and the middle 1731, and a second bend 1734 is disposed between the middle 1731 and the second end 1733.

The first section 1718-1 of the electrically thin resistive layer is disposed at the first end 1730, the second section 1718-2 is disposed at the first bend 1732, the third section 1718-3 is disposed at the second bend 1734, and the fourth section 1718-4 is disposed at the second end 1732. As shown, a gap is provided between each of the first through fourth sections 1718-1˜1718-4. Notably, one or more of the first through fourth sections 1718-1˜1718-4 may comprise a single section of the electrically thin resistive layer (i.e., no gaps in the section). Alternatively, one or more of the first through fifth sections 1718-1˜1718-5 may comprise a plurality of sections with gaps (not shown in FIG. 17). These sections and gaps may be as described above in connection with the representative embodiments of FIGS. 13 and 14. Moreover, and as described more fully below, the second and fourth sections 1718-2, 1718-4, disposed in the first and second bends 1732 and 1734, respectively, may be omitted.

As noted above, eliminating the electrically thin resistive layer in first and second bends 1732 and 1734 can reduce the TEM insertion loss due to the first and second bend 1732 and 1734. However, eliminating the electrically thin resistive layer will reduce the attenuation of higher order modes. As such, a trade-off has to be made in an effort to reduce the TEM insertion loss with an acceptable level of higher order mode energy in the coaxial transmission line. As such, in accordance with a representative embodiment, the elimination of the first and third sections 1718-2 and 1718-3 provides a comparatively low TEM insertion loss, while providing ample attenuation of higher order modes. However, in such a representative embodiment, the severity of the first and second bends 1732 and 1734 is limited to an Euler bend, such as described in the above-incorporated U.S. patent application No. (Attorney Docket No. 20170505-01). If the severity of the first and second bends 1732 and 1734 is too great, the energy of higher order modes can reach unacceptable values and interfere with the desired TEM mode. As noted above, the severity of the bends 1732 and 1734 may be determined empirically, based on the present teachings, to realize acceptable attenuation of higher order modes, while maintaining the TEM insertion loss to an acceptable level.

Again, in regions where comparatively severe (e.g., tight radius, non-Euler bends) bends occur in the coaxial cable 1700, the electrically thin resistive layer of the present teachings provides sufficient attenuation of higher order modes, while maintaining the TEM insertion loss to an acceptable level. As such, in representative embodiments where the first and second bends 1732 and 1734 are comparatively severe (again, tight radius, non-Euler bends), the second and fourth sections 1718-2 and 1718-4 have been found to provide sufficient attenuation of higher order modes, while maintaining the TEM insertion loss to an acceptable level. As noted above, the severity of the first and second bends 1732 and 1734 may be determined empirically, based on the present teachings, to realize acceptable attenuation of higher order modes, while maintaining the TEM insertion loss to an acceptable level.

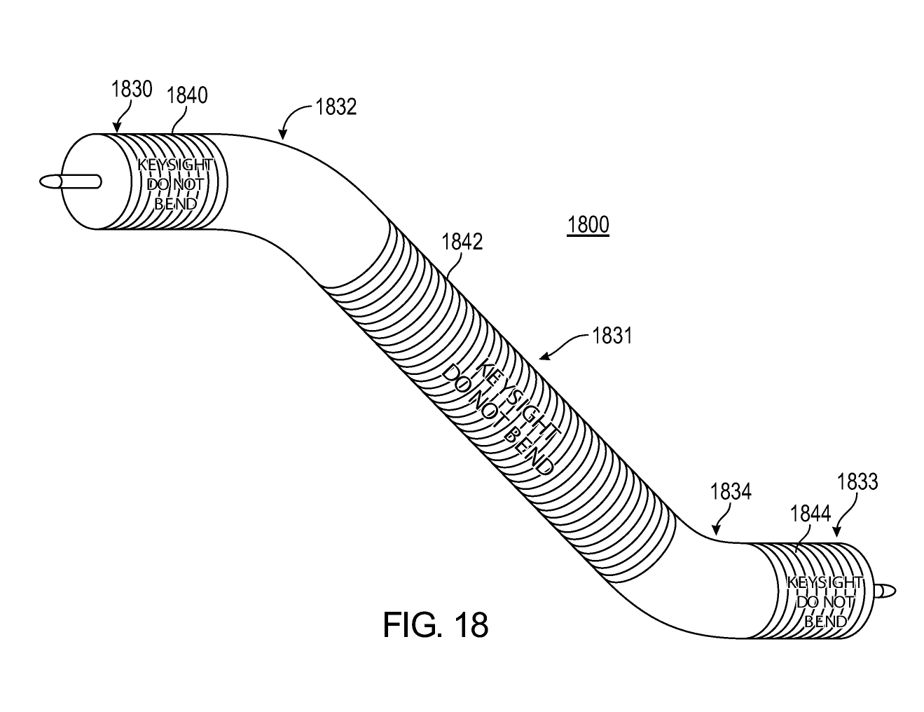

FIG. 18 is a perspective view of a coaxial transmission line 1800 in accordance with a representative embodiment. Often, aspects and details of the coaxial transmission line 1800 are common to those of the representative embodiments described above. These aspects and details may not be repeated in order to avoid obscuring the description of the presently described representative embodiments.

The coaxial transmission line 1800 includes a first end 1830, a middle 1831 and a second end 1833. A first bend 1832 is between the first end 1830 and the middle 1831; and a second bend 1834 is between the middle 1831 and the second end 1833.

As described above, the first end 1830, the middle 1831, and the second end 1833 may have respective sections of an electrically thin layer disposed therein. Because it is generally detrimental to the overall performance of the coaxial transmission line 1800, a first rigid section 1840, a second rigid section 1842, and a third rigid section 1844, are disposed over the outer sheath of the coaxial transmission line 1800, at the first end 1830, the middle 1831, and the second end 1833. More generally, the rigid sections may be provided at any location of coaxial transmission line 1800 where it is desired to maintain the coaxial transmission line 1800 comparatively straight.

The first˜third rigid sections 1840˜1844 may be made of any material suitable for providing the needed strength to prevent bending of the coaxial transmission line 1800 without interfering with the electrical performance of the coaxial transmission line 1800.

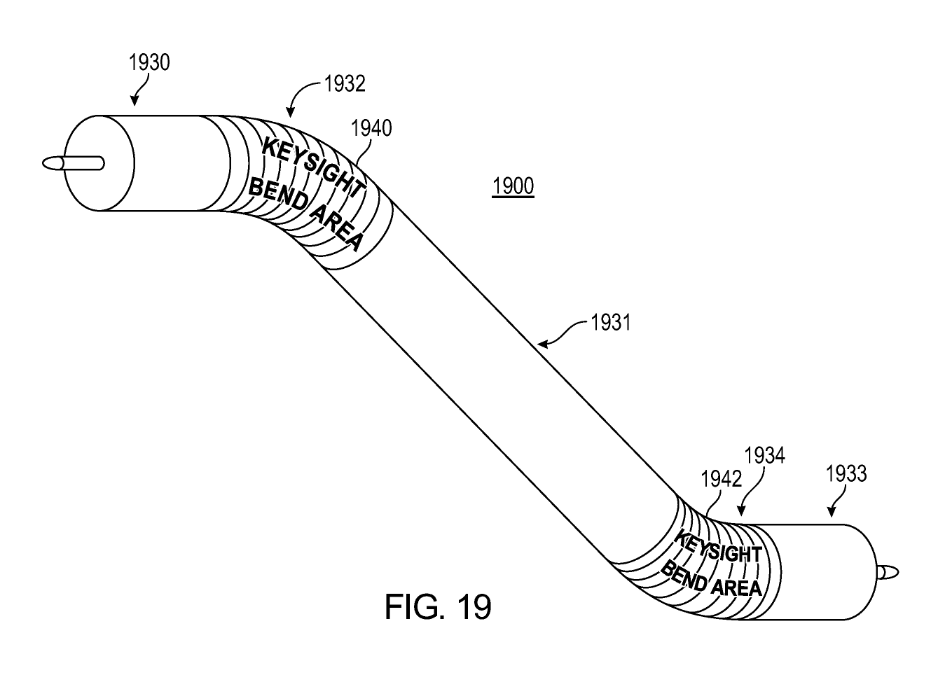

FIG. 19 is a perspective view of a coaxial transmission line 1900 in accordance with a representative embodiment. Often, aspects and details of the coaxial transmission line 1900 are common to those of the representative embodiments described above. These aspects and details may not be repeated in order to avoid obscuring the description of the presently described representative embodiments.

The coaxial transmission line 1900 includes a first end 1930, a middle 1931 and a second end 1933. A first bend 1932 is between the first end 1930 and the middle 1931; and a second bend 1934 is between the middle 1931 and the second end 1933.

For reasons described above, it is generally desirable to bend the coaxial transmission line 1900 in locations where there are no sections of an electrically thin resistive layer. As such, the coaxial transmission line 1900 has first region 1940 at the first bend 1932, and a second region 1942 at the second bend 1934 where there are no sections of the electrically thin resistive layer. The first and second regions 1940 and 1942 may have markings as shown to indicate a place where a bend can be provided, and may not have sections of rigid material located therein. Rather, the combination of the teachings of FIGS. 18 and 19 reveal a structure that is properly reinforced where bends are no desired, and has more flexible material (e.g., so-called flexible cable, or semi-flexible cable, or both) where bends are allowed.

While the invention has been illustrated and described in detail in the drawings and foregoing description, such illustrations and descriptions are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to an advantage.

While representative embodiments are disclosed herein, one of ordinary skill in the art appreciates that many variations that are in accordance with the present teachings are possible and remain within the scope of the appended claim set. The invention therefore is not to be restricted except within the scope of the appended claims.

We claim:

1. A signal transmission line comprising:
a first electrical conductor;
a second electrical conductor;
a dielectric region between the first electrical conductor and the second electrical conductor; and
an electrically thin resistive layer disposed within the dielectric region, and disposed between the first electrical conductor and the second electrical conductor, wherein a gap exists in the electrically thin resistive layer.

2. The signal transmission line of claim 1, wherein the electrically thin resistive layer is configured to be substantially transparent to a substantially transverse-electromagnetic (TEM) mode of transmission while substantially completely attenuating higher order modes of transmission, and the higher order modes of transmission are not substantially attenuated in the gaps.

3. The signal transmission line of claim 1, wherein the gap exists perimetrically in the electrically thin resistive layer.

4. The signal transmission line of claim 1, wherein the gap exists radially in the electrically thin resistive layer.

5. The signal transmission line of claim 1, further comprising a plurality of gaps, wherein some of the plurality of gaps exist perimetrically in the electrically thin resistive layer, and some of the plurality of gaps exist radially in the electrically thin resistive layer.

6. The signal transmission line of claim 5, wherein each of the plurality of gaps has a length, and each of the lengths is substantially the same.

7. The signal transmission line of claim 5, wherein each of the plurality of gaps has a length, and at least some of the lengths are not the same.

8. The signal transmission line of claim 1, wherein the gaps in the electrically thin resistive layer are arranged in a checkerboard pattern.

9. The signal transmission line of claim 2, wherein an electric field exists between the first electrical conductor and the second electrical conductor, the electric field having electric field lines that are perpendicular to the electrically thin resistive layer at each point of contact with the electrically thin resistive layer.

10. The signal transmission line of claim 9, wherein the first electrical conductor is substantially surrounded by the second electrical conductor, and is substantially located at a geometric center of the second electrical conductor.

11. The signal transmission line of claim 1, wherein the first electrical conductor is substantially surrounded by the second electrical conductor, and is offset relative to a geometric center of the second electrical conductor.

12. The signal transmission line of claim 1, wherein the electrically thin resistive layer comprises at least one of TaN, WSiN, resistively-loaded polyimide, graphite, graphene, transition metal dichalcogenide (TMDC), nichrome, nickel phosphorus, indium oxide, and tin oxide.

13. The signal transmission line of claim 1, wherein the electrically thin resistive layer has an electrical sheet resistance between 20-2500 ohms/sq.

14. The signal transmission line of claim 1, wherein the electrically thin resistive layer has an electrical sheet resistance between 20-200 ohms/sq.

15. The signal transmission line of claim 17, wherein a mechanical stiffener is disposed around an outer section of the end, or of the middle, or of both.

16. A coaxial transmission line comprising:
an inner electrical conductor;
an outer electrical conductor;
a dielectric region between the inner electrical conductor and the outer electrical conductor, wherein the dielectric region and the outer electrical conductor are disposed concentrically around the inner electrical conductor; and
an electrically thin resistive layer disposed within the dielectric region, between the inner electrical conductor and the outer electrical conductor, and substantially concentric with the inner and outer electrical conductors, wherein a gap exists in the electrically thin resistive layer.

17. The coaxial transmission line of claim 16, wherein the electrically thin resistive layer is configured to be substantially transparent to a substantially transverse-electromagnetic (TEM) mode of transmission while substantially completely attenuating higher order modes of transmission, and the higher order modes of transmission are not substantially attenuated in the gap.

18. The coaxial transmission line of claim 16, wherein the coaxial transmission line has an end and a bend, and a first section of the electrically thin resistive layer is disposed at the end, a second section of the electrically thin resistive layer is disposed in a bend, and the gap exists between the first and second sections of the electrically thin resistive layer.

19. The coaxial transmission line of claim 18, wherein the first section comprises additional gaps.

20. The coaxial transmission line of claim 18, wherein the second section comprises additional gaps.

21. The coaxial transmission line of claim 16, further comprising a plurality of gaps, wherein some of the plurality of gaps exist perimetrically in the electrically thin resistive layer, and some of the plurality of gaps exist radially in the electrically thin resistive layer.

22. The coaxial transmission line of claim 21, wherein each of the plurality of gaps has a length, and each of the lengths is substantially the same.

23. The signal transmission line of claim 21, wherein each of the plurality of gaps has a length, and at least some of the lengths are not the same.

24. The coaxial transmission line of claim 16, wherein the coaxial transmission line has an end and a bend, a section of the electrically thin resistive layer is disposed at the end, and none of the electrically thin resistive layer exists at the bend.

25. The coaxial transmission line of claim 16, wherein the gap is a first gap, and the coaxial transmission line comprises a second gap, the coaxial transmission line having a first end, a second end, and a middle, and a first section of the electrically thin resistive layer is disposed at the first end, a second section of the electrically thin resistive layer disposed at the second end, a third section of the electrically thin resistive layer is disposed in the middle, wherein the first gap is between the first section and the second section, and the second gap is between the second section and the third section.

26. The coaxial transmission line of claim 16, wherein the coaxial transmission line has a first end, a second end, and a middle, and a first section of the electrically thin resistive layer is disposed at the first end, a second section of the electrically thin resistive layer disposed at the second end, and none of the electrically thin resistive layer is disposed in the middle.

27. The coaxial transmission line of claim 18, wherein a mechanical stiffener is disposed around an outer section of the end, or of the middle, or of both.

28. The coaxial transmission line of claim 26, wherein the gap exists between the first end and the second end.

29. The coaxial transmission line of claim 16, wherein the gap exists perimetrically in the electrically thin resistive layer.

30. The coaxial transmission line of claim 16, wherein the gap exists radially in the electrically thin resistive layer.

31. The coaxial transmission line of claim 30, wherein additional gaps exist in one or more of the first section, the second section, and the third section.

32. The coaxial transmission line of claim 16, wherein the electrically thin resistive layer has an electrical sheet resistance between 20-200 ohms/sq.

33. The coaxial transmission line of claim 16, wherein the electrically thin resistive layer comprises at least one of TaN, WSiN, resistively-loaded polyimide, graphite, graphene, transition metal dichalcogenide (TMDC), nichrome, nickel phosphorus, indium oxide, and tin oxide.

34. The coaxial transmission line of claim 16, wherein the gaps in the electrically thin resistive layer are arranged in a checkerboard pattern.
